(19) United States
(12) Patent Application Publication
(10) Pub. No.: US 2015/0014720 A1
(43) Pub. Date: Jan. 15, 2015

(54) LIGHT EMITTING DIODE PACKAGE STRUCTURE

(71) Applicant: Lextar Electronics Corporation, Hsinchu (TW)

(72) Inventor: Yun-Yi Tien, Hsinchu City (TW)

(73) Assignee: Lextar Electronics Corporation, Hsinchu (TW)

(21) Appl. No.: 14/252,848

(22) Filed: Apr. 15, 2014

(30) Foreign Application Priority Data
Jul. 10, 2013 (TW) 102124725

(51) Int. Cl. H01L 33/48; H01L 33/60; H01L 33/50

(52) U.S. Cl. CPC H01L 33/483; H01L 33/50; H01L 33/60
USPC 257/98

(57) ABSTRACT

A LED package structure including a carrier and a light emitting diode (LED) chip is provided. The LED chip includes a substrate, a patterned structure, a first semiconductor layer, an active layer and a second semiconductor layer. The substrate has a first surface and a second surface opposite to the first surface. The patterned structure is formed on the second surface of the substrate. The first semiconductor layer is disposed on the first surface of the substrate. The active layer is disposed on a portion of a surface of the first semiconductor layer, and other portion of the surface not covered by the active layer is exposed. The second semiconductor layer is disposed on the active layer. The LED chip is disposed on the carrier by way of flip-chip so that the first and the second semiconductor layers face towards the carrier.

This application claims the benefit of Taiwan application Serial No. 102124725, filed Jul. 10, 2013, the subject matter of which is incorporated herein by reference.

### BACKGROUND OF THE INVENTION

1. Field of the Invention

The invention relates in general to an LED package structure, and more particularly to a package structure formed by an LED chip disposed on a carrier by way of flip-chip.

2. Description of the Related Art

Light emitting diode (LED) chip, having the advantages of long lifespan, small volume, high brightness and low power consumption, has been widely used in various fields such as indicator and backlight module. Along with the development in multi-color space and high brightness technology in recent years, the LED package structure has been used in the field of white light emitting technology to replace conventional fluorescent tube.

The LED chip is a semiconductor light emitting element, and mainly includes a substrate, an epitaxy layer and two electrodes. The epitaxy layer includes an N-type semiconductor layer, a P-type semiconductor layer and an active layer between the N-type and the P-type semiconductor layers. When a voltage is applied to two electrodes (positive and negative electrodes) of the LED, electrons will be combined with holes in the active layer and the energy is emitted in the form of light.

However, the substrate of the LED chip has a high coefficient of refraction, such that the light emitted within the substrate at an angle larger than a full reflection angle will experience full reflection on the surface of the substrate. Since a portion of the light is contained within the substrate and cannot be fully extracted, the extraction efficiency of the light will deteriorate.

### SUMMARY OF THE INVENTION

The invention is directed to a light emitting diode (LED) package structure, in which an LED chip is fixed on a carrier by way of flip-chip.

According to one embodiment of the present invention, a light emitting diode (LED) package structure including a carrier and an LED chip is provided. The LED chip includes a substrate, a patterned structure, a first semiconductor layer, an active layer and a second semiconductor layer. The substrate has a first surface and a second surface opposite to the first surface. The patterned structure is formed on the second surface of the substrate. The first semiconductor layer is disposed on the first surface of the substrate. The active layer is disposed on a portion of a surface of the first semiconductor layer, and other portion of the surface not covered by the active layer is exposed. The second semiconductor layer is disposed on the active layer. The LED chip is disposed on the carrier by way of flip-chip such that the first and the second semiconductor layers face towards the carrier.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of an LED package structure according to an embodiment of the invention.

FIGS. 2A˜2C are schematic diagrams of patterned structures of different shapes.

FIG. 3 is a schematic diagram of an LED package structure according to an embodiment of the invention.

FIGS. 4A˜4D respectively are schematic diagrams of an LED package structure according to an embodiment of the invention.

FIGS. 5A˜5B respectively are schematic diagrams of an LED package structure according to an embodiment of the invention.

FIGS. 6A˜6B respectively are schematic diagrams of an LED package structure according to an embodiment of the invention.

### DETAILED DESCRIPTION OF THE INVENTION

The LED package structure disclosed in the present embodiment includes a light emitting diode (LED) chip and a patterned structure. The LED chip is disposed on a carrier by way of flip-chip. The patterned structure is formed on the LED chip. The patterned structure, which can be realized by any one of micro-structures, such as a nano-rod structure, a conical structure, a trapezoidal structure or a combination thereof, is formed on the substrate of the LED chip and has a non-flat surface. The patterned structure can be formed by an etching process with an etching solution or an ablating process with a laser light of high power. The non-flat surface of the patterned structure scatters the light emitted by the LED chip and increases light output, so as to increase the extraction efficiency of the light emitted by the LED package structure. The LED package structure can further improve color uniformity of emission spectrum through a wavelength conversion material contained in an underfill and/or an encapsulant or through a wavelength conversion layer disposed on the patterned structure.

A number of embodiments are disclosed below for elaborating the invention. However, the embodiments of the invention are for detailed descriptions only, not for limiting the scope of protection of the invention.

### First Embodiment

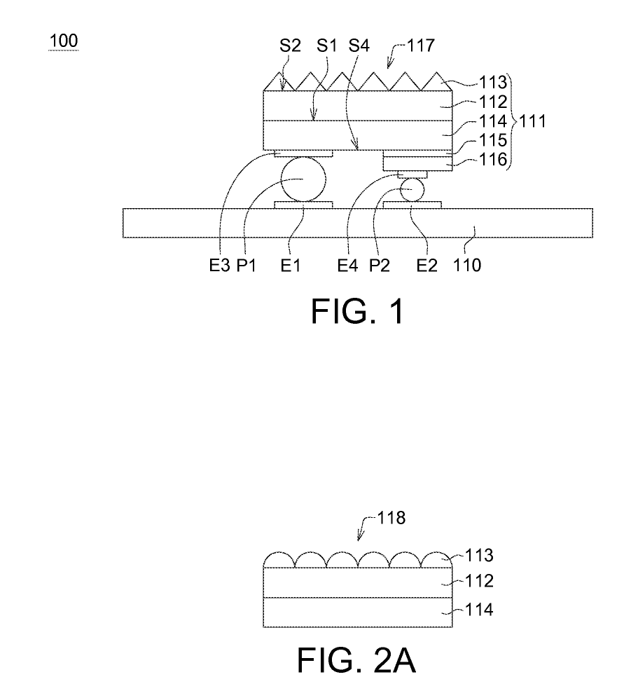

Referring to FIG. 1, a schematic diagram of an LED package structure 100 according to an embodiment of the invention is shown. The LED package structure 100 includes a carrier 110 and a light emitting diode (LED) chip 111. The carrier 110 can be a soft or a rigid substrate such as a printed circuit board, a metal substrate, a ceramic substrate or a lead frame. The LED chip 111 can be an LED emitting any color light such as an LED chip of blue light or ultra-violet light.

Preferably, the carrier 110 includes a first electrode E1 and a second electrode E2 thereon, and the LED chip 111 includes a third electrode E3 and a fourth electrode E4 thereon. The first electrode E1 is electrically connected to the third electrode E3, and the second electrode E2 is electrically connected to the fourth electrode E4.

In the present embodiment, the LED package structure 100 further includes a first conductor P1 and a second conductor P2, the first conductor P1 electrically connects the first electrode E1 and the third electrode E3, and the second conductor P2 electrically connects the second electrode E2 and the fourth electrode E4, such that the LED chip 111 is disposed on the carrier 110 by way of flip-chip and the first semiconductor layer 114 and the second semiconductor layer 116 face towards the carrier 110.

Referring to FIG. 1, the LED chip 111 includes a substrate 112, a patterned structure 113, a first semiconductor layer 114, an active layer 115 and a second semiconductor layer 116. The substrate 112 has a first surface S1 and a second surface S2 opposite to the first surface S1. The substrate 112 can be a sapphire substrate or an SiC substrate. The epitaxy reaction is performed on the substrate 112 to make the first semiconductor layer 114, the active layer 115 and the second semiconductor layer 116 sequentially formed and stacked on the first surface S1 of the substrate 112.

The first semiconductor layer 114 is disposed on the first surface S1 of the substrate 112. The active layer 115 is disposed on a portion of the surface S4 of the first semiconductor layer 114, and other portion of the first semiconductor layer 114 not covered by the active layer 115 is exposed. The second semiconductor layer 116 is disposed on the active layer 115.

Besides, the third electrode E3 is disposed on the exposed surface of the first semiconductor layer 114, such that the third electrode E3 disposed on the first semiconductor layer 114 is electrically connected and opposite to the first electrode E1. The fourth electrode E4, disposed on the second semiconductor layer 116, together with the third electrode E3 face towards the carrier 110, such that the fourth electrode E4 disposed on the second semiconductor layer 116 is electrically connected and opposite to the second electrode E2.

It can be known from above disclosure that the LED chip 111 is disposed on the carrier 110 by way of flip-chip such that the first semiconductor layer 114 and the second semiconductor layer 116 face towards the carrier 110. That is, the first semiconductor layer 114 and the second semiconductor layer 116 are located on one side of the substrate 112 relatively closer to the carrier 110, and the patterned structure is located on the other side of the substrate 112 relatively farther away from the carrier 110.

The active layer 115 is located between the first semiconductor layer 114 and the second semiconductor layer 116 having opposite polarities. The active layer 115 can be formed by a III-V compound semiconductor, such that electrons and holes which are conductive and transferred through the first semiconductor layer 114 and the second semiconductor layer 116 will be combined in the active layer and the energy is emitted in the form of light.

The patterned structure 113 is formed on the second surface S2 of the substrate 112, and has a non-flat surface 117. As indicated in FIG. 1, the patterned structure 113 is such as a conical micro-structure, a triangular pyramid micro-structure or a square based pyramid micro-structure, and the top surface of the patterned structure 113 is a non-flat surface 117 with a conical cross-section.

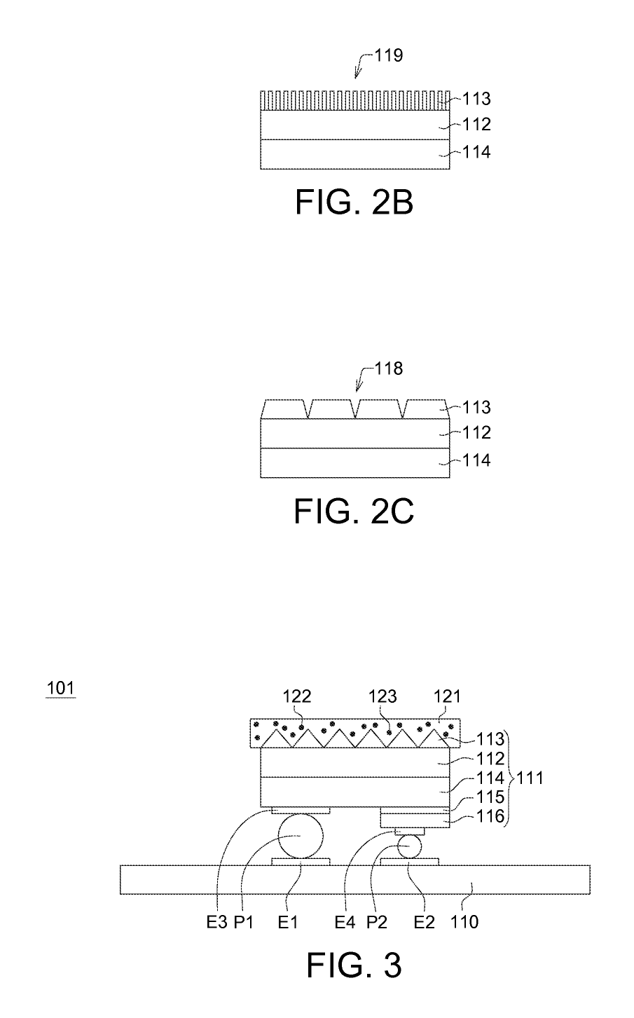

Nonetheless, the cross-sectional shape of the non-flat surface 117 is not restricted, and can be any shape such as cone, cylinder, semi-circle, and trapezoid or a combination thereof. Referring to FIGS. 2A˜2C, patterned structures 113 of different shapes are shown. As indicated in FIG. 2A, the patterned structure 113 is a semi-circular micro-structure 118. As indicated in FIG. 2B, the patterned structure 113 is cylindrical micro-structure 119 such as a nano-rod structure. As indicated in FIG. 2C, the patterned structure 113 is a trapezoidal micro-structure 120.

According to the generally known technologies, the substrate 112 is realized by a sapphire substrate or an SiC substrate with high index of refraction, such that the light is reflected back to the LED chip 111 by the substrate 112 and it is difficult for the light to be outputted via the second surface S2 of the substrate 112. Thus, the extraction efficiency of the light is thus affected. In the present embodiment, the patterned structure 113 has the non-flat surface 117 which scatters the light emitted by the LED chip 111 to increase light output, so as to increase the extraction efficiency of the light emitted by the LED package structure 100.

In the present embodiment, the second surface S2 of the substrate 112 is roughed or patterned by an etching process, such that the substrate 112 has a roughed surface where the patterned structure 113 is formed. In comparison to the generally known technology which lifts off the sapphire substrate by using laser, the present invention adopts an etching process in which the substrate 112 is etched without affecting the formation of epitaxy of the semiconductor layer on the substrate 112. The present invention increases the extraction efficiency of the light, reduces the cost and increases the yield rate of manufacturing process.

### Second Embodiment

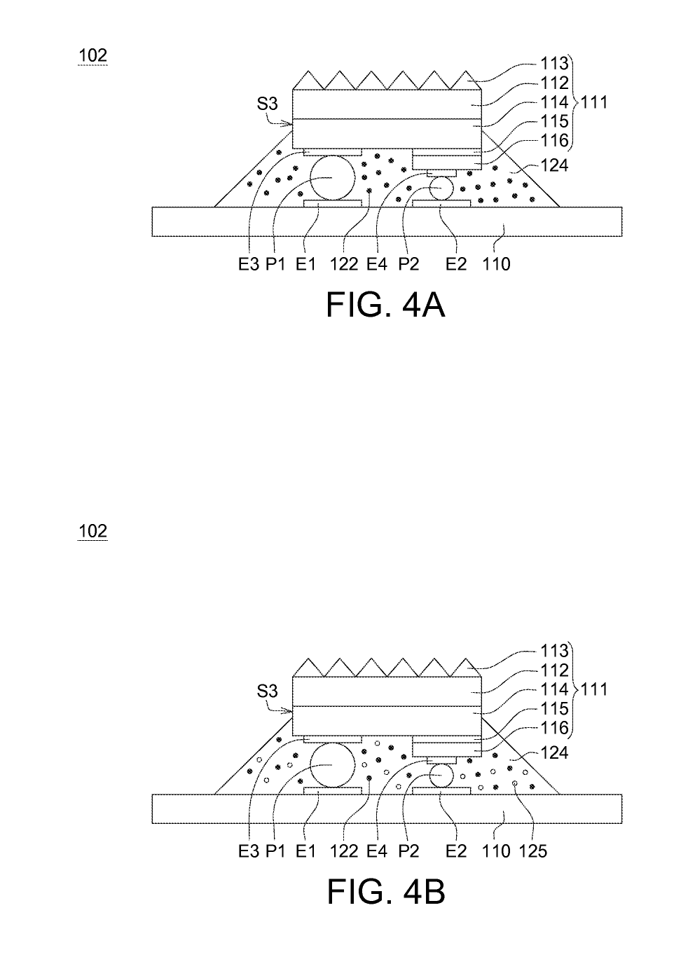

Referring to FIG. 3, a schematic diagram of an LED package structure 101 according to an embodiment of the invention is shown. The present embodiment is different from the first embodiment in that the LED package structure 101 further includes a wavelength conversion layer 121 disposed on the patterned structure 113. The wavelength conversion layer 121 includes a first wavelength conversion material 122 and/or a second wavelength conversion material 123. The wavelength conversion layer 121 is capable of emitting a second light of wavelength λ2 and/or a third light of wavelength λ3 after having been irradiated by the first light of wavelength λ1 emitted by the active layer 115, wherein λ2>λ1, λ3>λ1. For example, the first light is blue light or ultra-violet light. The first wavelength conversion material 122 is capable of emitting a second light of yellow light or red light wavelength after having been irradiated by the first light. The second wavelength conversion material 123 is capable of emitting a third light of green light wavelength after having been irradiated by the first light.

After the first light, the second light and the third light of different wavelengths (such as the red light, the blue light and the green light) are mixed, a white light of full band wavelength can be generated to improve the color uniformity of emission spectrum. Thus, the LED package structure can avoid the conventional problem in color shift.

### Third Embodiment

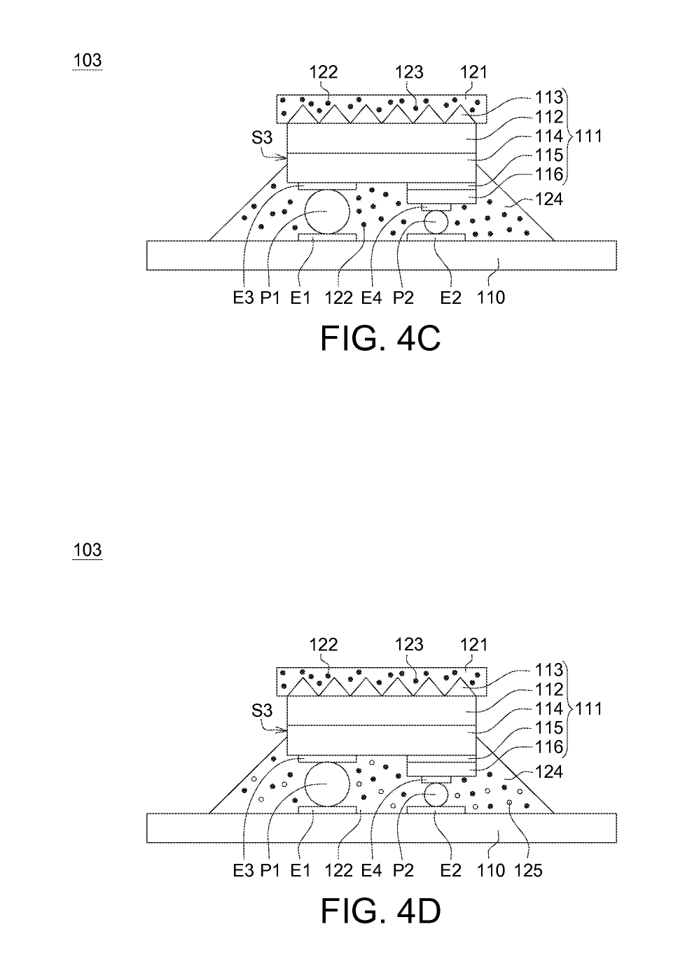

Referring to FIGS. 4A˜4B, schematic diagrams of an LED package structure 102 according to an embodiment of the invention are respectively shown. the present embodiment is different from the first embodiment in that the LED package structure 102 further includes an underfill 124 for encapsulating the first conductor P1, the second conductor P2 and a portion of lateral surface S3 of the LED chip 111

As indicated in FIG. 4A, the underfill 124 includes a first wavelength conversion material 122. The first wavelength conversion material 122 is capable of emitting a second light of wavelength λ2 after having been irradiated by the first light of wavelength λ1 emitted by the active layer 115, and λ2>λ1. For example, the first light is a blue light or ultra-violet light. After the first wavelength conversion material 122 is irradiated by the first light, the first wavelength conversion material 122 is capable of emitting a second light of yellow light or red light wavelength.

In the LED package structure 102 as indicated in FIG. 4B, the underfill 124 has the first wavelength conversion material 122 as well as a composition having reflective particles 125 for reflecting the first light and/or the second light. That is, when the underfill 124 includes the composition having reflective particles 125, the first light entering the underfill 124 can be reflected by the composition having reflective particles 125 and mixed with the second light of wavelength λ2 to change and improve the color uniformity of emission spectrum and further resolve the conventional problem in color shift.

Referring to FIGS. 4C˜4D, schematic diagrams of an LED package structure 103 according to an embodiment of the invention are respectively shown. The wavelength conversion layer 121 as indicated in FIG. 3 can be applied in the LED package structure 103 of the present embodiment as indicated in FIG. 4C and FIG. 4D.

In the present embodiment, the first light of wavelength λ1 can be converted to the second light of wavelength λ2 and/or the third light of wavelength λ3 through the wavelength conversion layer 121, converted to the second light of wavelength λ2 through the first wavelength conversion material 122 in the underfill 124 or used for reflecting the first light of wavelength λ1 through the composition having reflective particles 125 in the underfill 124. Thus, the LED package structure of the present embodiment can resolve a generally known problem in color shift.

### Fourth Embodiment

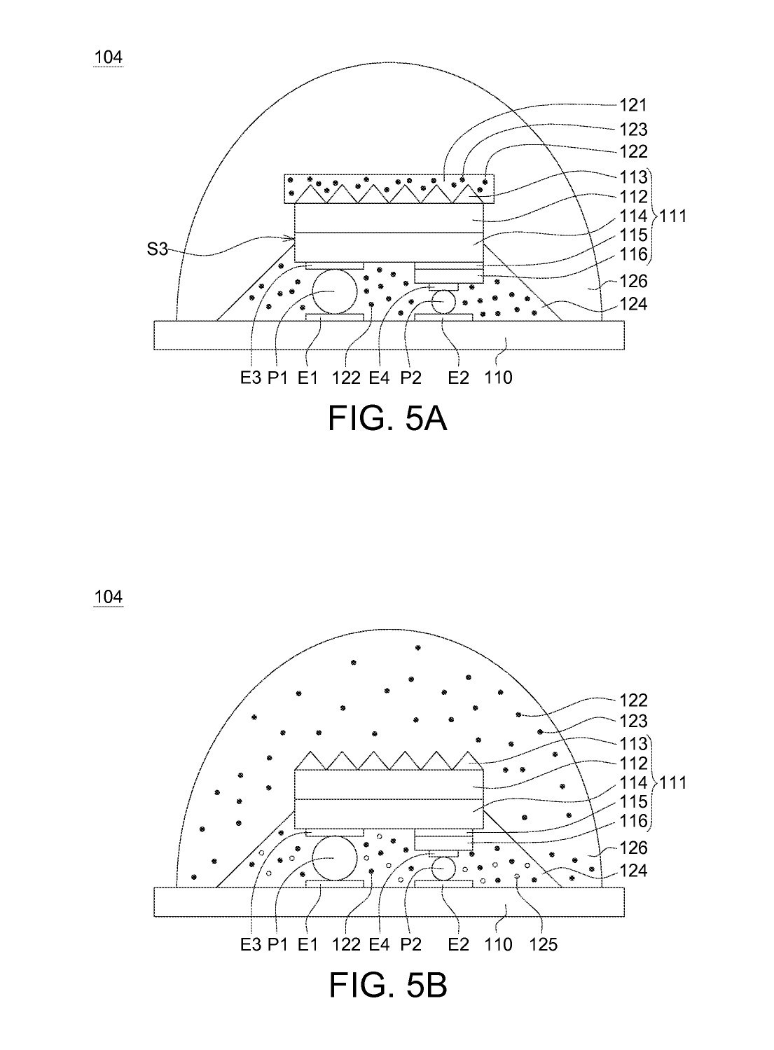

Referring to FIGS. 5A˜5B, schematic diagrams of an LED package structure 104 according to an embodiment of the invention are respectively shown. the present embodiment is different from the third embodiment in that the LED package structure 104 further includes an encapsulant 126 encapsulating wavelength conversion layer 121 and the LED chip 111 as indicated in FIG. 5A. Or, the encapsulant 126 encapsulates the LED chip 111 as indicated in FIG. 5B.

In the present embodiment, the LED chip 111 having the wavelength conversion layer 121 and the underfill 124 is encapsulated in a liquid colloid such as a mold glue, which is dispensed into a mold, cured and then released from the mold to form the encapsulant 126.

As indicated in FIG. 5B, the encapsulant 126 further includes a first wavelength conversion material 122 and/or a second wavelength conversion material 123. That is, in an embodiment without the wavelength conversion layer 121 of FIG. 5A, the first wavelength conversion material 122 and/or the second wavelength conversion material 123 having the same effect can be added to the encapsulant 126 for converting the first light of wavelength λ1 to the second light of wavelength λ2 and/or the third light of wavelength λ3. Thus, the LED package structure of the present embodiment can resolve a generally known problem in color shift.

### Fifth Embodiment

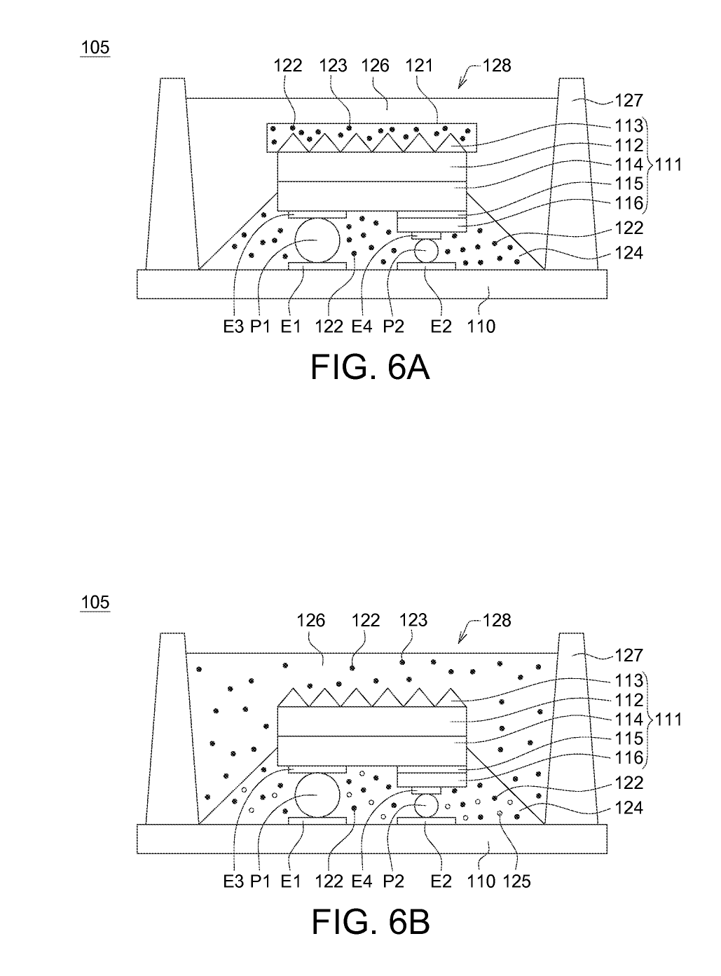

Referring to FIGS. 6A˜6B, schematic diagrams of an LED package structure 105 according to an embodiment of the invention are respectively shown. The present embodiment is different from the fourth embodiment in that the LED package structure 105 further includes a barrier wall structure 127 disposed on the carrier 110. The barrier wall structure 127 surrounds the wavelength conversion layer 121 and the LED chip 111 to form a recess 12 into which the encapsulant 126 is interposed as indicated in FIG. 6A. Or, the barrier wall structure 127 surrounds the LED chip 111 to form a recess 128 into which the encapsulant 126 is interposed as indicated in FIG. 6B.

As indicated in FIG. 6B, the encapsulant 126 further includes the first wavelength conversion material 122 and/or the second wavelength conversion material 123. That is, in an embodiment without the wavelength conversion layer 121 of FIG. 6A, the first wavelength conversion material 122 and/or the second wavelength conversion material 123 having the same effect can be added to the encapsulant 126 for converting the first light of wavelength λ1 to the second light of wavelength λ2 and/or the third light of wavelength λ3. Thus, the LED package structure of the present embodiment can resolve a generally known problem in color shift.

The wavelength conversion layer 121 can be a fluorescent conversion layer, and the wavelength conversion material and the second wavelength conversion material 123 can be a fluorescent powder. With respect to the LED chips 111 of different color light, different varieties of fluorescent powders can be used for mixing of light. Particularly, the underfill 124 can be dispensed under the LED chip 111 disposed on the carrier 110 by way of flip-chip without adhering the fluorescent layer on the bottom surface of the LED chip, not only simplifying the manufacturing process but also increasing color uniformity.

In each embodiment, the patterned structure 113 scatters the light emitted by the LED chip 111 and increases light output, so as to increase the extraction efficiency of the LED package structures 100˜105 disclosed above in different implementations.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light emitting diode (LED) package structure, comprising:
a carrier; and
a light emitting diode (LED) chip, comprising:
a substrate having a first surface and a second surface opposite to the first surface;
a patterned structure formed on the second surface of the substrate;
a first semiconductor layer disposed on the first surface of the substrate;
an active layer disposed on a portion of the surface of the first semiconductor layer, and other portion of the first semiconductor layer not covered by the active layer is exposed; and
a second semiconductor layer disposed on the active layer;
wherein, the LED chip is disposed on the carrier by way of flip-chip with the first and the second semiconductor layers facing towards the carrier.

2. The LED light emitting structure according to claim 1, wherein the patterned structure has a non-flat surface whose cross-section is one of cone, cylinder, semi-circle, trapezoid or a combination thereof.

3. The LED package structure according to claim 2, wherein the carrier further comprises a first electrode and a second electrode disposed thereon.

4. The LED package structure according to claim 3, wherein the LED chip further comprises:
a third electrode disposed on the exposed portion of the first semiconductor layer; and
a fourth electrode disposed on the second semiconductor layer;
wherein, the first electrode is electrically connected to the third electrode, and the second electrode is electrically connected to the fourth electrode.

5. The LED package structure according to claim 4, further comprising:
a first conductor electrically connecting the first electrode and the third electrode; and
a second conductor electrically connecting the second electrode and the fourth electrode.

6. The LED package structure according to claim 5, further comprising an underfill for encapsulating the first conductor, the second conductor and a portion of a lateral surface of the LED chip.

7. The LED package structure according to claim 6, wherein the underfill comprises a first wavelength conversion material capable of emitting a second light of wavelength λ2 after having been irradiated by a first light of wavelength λ1 emitted by the active layer, and λ2>λ1.

8. The LED package structure according to claim 7, wherein the underfill further comprises a composition of reflective particles for reflecting the first light.

9. The LED package structure according to claim 8, further comprising a wavelength conversion layer disposed on the patterned structure, the wavelength conversion layer comprises a first wavelength conversion material and/or a second wavelength conversion material, such that after the wavelength conversion layer is irradiated by the first light of wavelength λ1 emitted by the active layer, the wavelength conversion layer is capable of emitting the second light of wavelength λ2 and/or the third light of wavelength λ3, and λ2>λ1, λ3>λ1.

10. The LED package structure according to claim 9, further comprising an encapsulant encapsulating the wavelength conversion layer and the LED chip.

11. The LED package structure according to claim 10, further comprising a barrier structure disposed on the carrier and surrounding the wavelength conversion layer and the LED chip for forming a recess into which the encapsulant is interposed.

12. The LED package structure according to claim 11, wherein the encapsulant further comprises the first wavelength conversion material and/or the second wavelength conversion material.

13. The LED package structure according to claim 1, wherein the substrate is a sapphire substrate or a SiC substrate.

14. The LED package structure according to claim 1, wherein the LED chip is an LED chip of blue light or ultra-violet light.

15. The LED package structure according to claim 1, further comprising a wavelength conversion layer disposed on the patterned structure, the wavelength conversion layer comprises a first wavelength conversion material and/or a second wavelength conversion material, such that after the wavelength conversion layer is irradiated by the first light of wavelength λ1 emitted by the active layer, the wavelength conversion layer is capable of emitting the second light of wavelength λ2 and/or the third light of wavelength λ3, and λ2>λ1, λ3>λ1.
